(19) United States
(12) Patent Application Publication
(10) Pub. No.: US 2025/0132119 A1
(43) Pub. Date: Apr. 24, 2025

(54) MULTI-ELECTRON BEAM IMAGE ACQUISITION APPARATUS, MULTI-ELECTRON BEAM IMAGE ACQUISITION METHOD, ELECTRON BEAM IMAGE ACQUISITION APPARATUS, AND ELECTRON BEAM IMAGE ACQUISITION METHOD

(71) Applicant: NuFlare Technology, Inc., Yokohama-shi (JP)

(72) Inventors: Kazuhiko INOUE, Yokohama-shi (JP); Munehiro OGASAWARA, Hiratsuka-shi (JP); Masataka SHIRATSUCHI, Yokohama-shi (JP)

(73) Assignee: NuFlare Technology, Inc., Yokohama-shi (JP)

(21) Appl. No.: 19/009,902

(22) Filed: Jan. 3, 2025

Related U.S. Application Data
(63) Continuation of application No. PCT/JP2023/024464, filed on Jun. 30, 2023.

(30) Foreign Application Priority Data
Jul. 6, 2022 (JP) 2022-109275
Jun. 29, 2023 (JP) 2023-107379

(51) Int. Cl. H01J 37/147; H01J 37/05; H01J 37/153

(52) U.S. Cl. CPC H01J 37/1477; H01J 37/05; H01J 37/153; H01J 2237/103; H01J 2237/1516; H01J 2237/1534

(57) ABSTRACT

According to one aspect of the present invention, a multi-electron beam image acquisition apparatus, includes: a plurality of first electrostatic deflectors in two stages, each of the first electrostatic deflectors having a plurality of electrodes of quadrupoles or more, configured to deflect multiple primary electron beams collectively to scan a substrate with the multiple primary electron beams; a potential application circuit configured to apply a retarding potential to the substrate; a first determination circuit configured to determine a first phase difference of deflection directions for the plurality of first electrostatic deflectors so as to reduce aberration caused by deflection of the multiple primary electron beams according to a magnitude of the retarding potential; and a deflection control circuit configured to apply an individual potential according to the first phase difference of the deflection directions to each electrode of the plurality of first electrostatic deflectors.

### CROSS-REFERENCE TO RELATED APPLICATION

This application is a continuation application based upon and claims the benefit of priority from prior Japanese Patent Application No. 2022-109275 (application number) filed on Jul. 6, 2022 in Japan, Japanese Patent Application No. 2023-107379 (application number) filed on Jun. 29, 2023 in Japan, and International Application PCT/JP2023/024464, the International Filing Date of which is Jun. 30, 2023. The contents described in JP2022-109275, JP2023-107379 and PCT/JP2023/024464 are incorporated herein by reference.

### BACKGROUND OF THE INVENTION

### Field of the Invention

One aspect of the present invention relates to a multi-electron beam image acquisition apparatus, a multi-electron beam image acquisition method, an electron beam image acquisition apparatus, and an electron beam image acquisition method. For example, the invention relates to an image acquisition method of a multi-beam inspection apparatus that performs pattern inspection using a secondary electron image caused by emission of multiple primary electron beams.

### Related Art

In recent years, with the increase in the integration and capacity of a large-scale integrated circuit (LSI), the circuit pattern line width required for semiconductor devices has become narrower and narrower. In addition, improving the yield is indispensable for manufacturing the LSI, which requires a high manufacturing cost. However, as represented by 1-gigabit class DRAM (random access memory), the patterns forming the LSI are on the order of submicron to nanometer. In recent years, with the decrease in the dimensions of LSI patterns formed on a semiconductor wafer, dimensions that should be detected as pattern defects are also extremely small. Therefore, in order to inspect defects in ultra-fine patterns transferred onto a semiconductor wafer, it is necessary to capture a high-precision image.

For example, the inspection apparatus scans an inspection target substrate with multiple primary electron beams using an electron beam and detects secondary electrons corresponding to each beam emitted from the inspection target substrate to capture a pattern image. Such scanning is performed by a deflector. For example, when multiple primary electron beams are deflected using an electrostatic deflector, aberrations according to the amount of scanning occur. Among such aberrations, for example, coma aberration is difficult to dynamically correct with a deflector. Therefore, the coma aberration can be corrected by arranging two-stage electrostatic deflectors, which are located up and down, with a phase shift (see, for example, JP-A-2008-153131). Thus, the method of correcting aberrations by mechanically shifting the phases of the two-stage electrostatic deflectors located up and down is effective when the energy state of the beam is uniquely determined. However, when the energy state of the beam changes, the effective phase difference for correcting aberrations changes, making the method difficult to use. For example, there is a need to change the landing energy of the electron beam onto the inspection target substrate. In image acquisition using an electron beam, there is an optimum landing energy depending on the yield of the target object to be inspected. For this reason, it is necessary to change the landing energy in accordance with the target object when capturing an image. When the landing energy is changed, the energy state of the beam changes. As a result, the effective phase difference for correcting aberrations changes. Such a problem is not limited to the inspection apparatus, and may occur similarly in all apparatuses for acquiring an image using multiple electron beams.

### BRIEF SUMMARY OF THE INVENTION

According to one aspect of the present invention, a multi-electron beam image acquisition apparatus, includes:
a stage, a substrate being placed on the stage;
a plurality of first electrostatic deflectors in two stages, each of the first electrostatic deflectors having a plurality of electrodes of quadrupoles or more, configured to deflect multiple primary electron beams collectively to scan the substrate with the multiple primary electron beams;
a separator configured to separate, from the multiple primary electron beams, multiple secondary electron beams emitted due to irradiation of the substrate with the multiple primary electron beams;
a multi-detector configured to detect the multiple secondary electron beams separated from the multiple primary electron beams;
a potential application circuit configured to apply a retarding potential to the substrate;
a first determination circuit configured to determine a first phase difference of deflection directions for the plurality of first electrostatic deflectors so as to reduce aberration caused by deflection of the multiple primary electron beams according to a magnitude of the retarding potential; and
a deflection control circuit configured to apply an individual potential according to the first phase difference of the deflection directions to each electrode of the plurality of first electrostatic deflectors.

According to another aspect of the present invention, a multi-electron beam image acquisition method, includes:

Scanning a substrate placed on a stage with multiple primary electron beams by collectively deflecting the multiple primary electron beams using a plurality of first electrostatic deflectors in two stages each having a plurality of electrodes of quadrupoles or more;
separating, from the multiple primary electron beams, multiple secondary electron beams emitted due to irradiation of the substrate with the multiple primary electron beams;
detecting the multiple secondary electron beams separated from the multiple primary electron beams and outputting secondary electron images based on signals of detected multiple primary electron beams;
applying a retarding potential to the substrate;
determining a first phase difference of deflection directions for the plurality of first electrostatic deflectors so as to reduce aberration caused by deflection of the multiple primary electron beams according to a magnitude of the retarding potential; and
applying an individual potential according to the first phase difference of the deflection directions to each electrode of the plurality of first electrostatic deflectors.

According to yet another aspect of the present invention, an electron beam image acquisition apparatus, includes:
a stage, a substrate being placed on the stage;
a plurality of first deflectors in two or more stages, each of the plurality of first deflectors having four or more poles, configured to deflect primary electron beam to scan the substrate with the primary electron beam;
a separator configured to separate, from the primary electron beam, a secondary electron beam emitted due to irradiation of the substrate with the primary electron beam;
a detector configured to detect the secondary electron beam separated from the primary electron beam;
a potential application circuit configured to apply a retarding potential to the substrate;
a first determination circuit configured to determine at least one of a first deflection angle ratio for the plurality of first deflectors in the two or more stages and a first phase difference of deflection directions for the plurality of first deflectors in the two or more stages so that a deflection aberration is equal to or less than a predetermined threshold value according to a magnitude of the retarding potential; and
a deflection control circuit configured to control the plurality of first deflectors in the two or more stages according to at least one of a determined first deflection angle ratio and a determined first phase difference.

According to yet another aspect of the present invention, an electron beam image acquisition method, includes:
scanning a substrate placed on a stage with a primary electron beam by deflecting the primary electron beam using a plurality of first deflectors in two or more stages, each of the first deflectors having four or more poles;
separating, from the primary electron beam, a secondary electron beam emitted due to irradiation of the substrate with the primary electron beam;
detecting the secondary electron beam separated from the primary electron beam and outputting a detected secondary electron image;
applying a retarding potential to the substrate;
determining at least one of a first deflection angle ratio for the plurality of first deflectors in the two or more stages and a first phase difference of deflection directions of the plurality of first deflectors in the two or more stages so that a deflection aberration is equal to or less than a predetermined threshold value according to a magnitude of the retarding potential; and
controlling the plurality of first deflectors in the two or more stages according to at least one of a determined first deflection angle ratio and a determined first phase difference.

According to yet another aspect of the present invention, a multi-electron beam image acquisition apparatus, includes:
a stage, a substrate being placed on the stage;
a plurality of first electrostatic deflectors in two or more stages, each of the first electrostatic deflectors having a plurality of electrodes of quadrupoles or more, configured to deflect multiple primary electron beams collectively to scan the substrate with the multiple primary electron beams;
a separator configured to separate, from the multiple primary electron beams, multiple secondary electron beams emitted due to irradiation of the substrate with the multiple primary electron beams;
a multi-detector configured to detect the multiple secondary electron beams separated from the multiple primary electron beams;
a potential application circuit configured to apply a retarding potential to the substrate;
a first determination circuit configured to determine a first phase difference of deflection directions for the plurality of first electrostatic deflectors in the two or more stages so as to reduce aberration caused by deflection of the multiple primary electron beams according to a magnitude of the retarding potential; and
a deflection control circuit configured to apply an individual potential according to the first phase difference of the deflection directions to each electrode of the plurality of first electrostatic deflectors in the two or more stages.

According to yet another aspect of the present invention, a multi-electron beam image acquisition method, includes:

Scanning a substrate placed on a stage with multiple primary electron beams by collectively deflecting the multiple primary electron beams using a plurality of first electrostatic deflectors in two or more stages, each of the plurality of first electrostatic deflectors having a plurality of electrodes of quadrupoles or more;
separating, from the multiple primary electron beams, multiple secondary electron beams emitted due to irradiation of the substrate with the multiple primary electron beams;
detecting the multiple secondary electron beams separated from the multiple primary electron beams and outputting a detected secondary electron image;
applying a retarding potential to the substrate;
determining a first phase difference of deflection directions for the plurality of first electrostatic deflectors in the two or more stages so as to reduce aberration caused by deflection of the multiple primary electron beams according to a magnitude of the retarding potential; and
applying an individual potential according to the first phase difference of the deflection directions to each electrode of the plurality of first electrostatic deflectors in the two or more stages.

### BRIEF DESCRIPTION OF THE DRAWINGS

FIG. 1 is a configuration diagram showing the configuration of a pattern inspection apparatus according to Embodiment 1;

FIG. 2 is a conceptual diagram showing the configuration of a shaping aperture array substrate according to Embodiment 1;

FIG. 3 is a diagram showing an example of a plurality of chip regions formed on a semiconductor substrate in Embodiment 1;

FIG. 4 is a diagram for explaining image acquisition processing in Embodiment 1;

FIG. 5 is a top view showing an example of the arrangement of two-stage deflectors in a comparative example of Embodiment 1;

FIG. 6 is a top view showing an example of the arrangement of two-stage deflectors in Embodiment 1;

FIG. 7 is a diagram showing an example of the incidence angle of a beam in Embodiment 1;

FIG. 8A is a diagram showing, by vectors, an example of the amount of deflection by a plurality of deflectors on a deflector surface in Embodiment 1;

FIG. 8B is a diagram showing, by vectors, an example of the amount of deflection by a plurality of deflectors on a target object surface in Embodiment 1;

FIG. 9 is a block diagram showing an example of an internal configuration of a phase difference control circuit in Embodiment 1;

FIG. 10 is a diagram showing an example of a relationship table (1) showing the relationship among landing energy, phase difference, and retarding potential associated with scanning using multiple primary electron beams in Embodiment 1;

FIG. 11 is a diagram showing an example of a relationship table (2) showing the relationship among landing energy, phase difference, and retarding potential associated with deflection back using multiple secondary electron beams in Embodiment 1;

FIG. 12 is a configuration diagram showing the configuration of a pattern inspection apparatus in Modification Example 1 of Embodiment 1;

FIG. 13 is a diagram for explaining the deflection angles of two-stage deflectors in Modification Example 2 of Embodiment 1;

FIG. 14 is a diagram for explaining a phase difference between two-stage deflectors in Modification Example 2 of Embodiment 1;

FIG. 15 is a diagram showing an example of the relationship among landing energy, deflection aberration, and phase difference in Modification Example 2 of Embodiment 1;

FIG. 16 is a diagram showing an example of the relationship among landing energy, deflection aberration, and deflection angle ratio in Modification Example 2 of Embodiment 1; and

FIG. 17 is a diagram showing another example of the internal configuration of a phase difference calculation circuit in Modification Example 2 of Embodiment 1.

### DETAILED DESCRIPTION OF THE INVENTION

In the following embodiments, there are provided an apparatus and a method that can correct aberrations according to the amount of scanning by deflectors even when the energy state of a beam changes.

In the following embodiments, a multi-electron beam inspection apparatus will be described as an example of a multi-electron beam image acquisition apparatus. However, the image acquisition apparatus is not limited to the inspection apparatus, and may be any apparatus that acquires an image using multiple beams.

### Embodiment 1

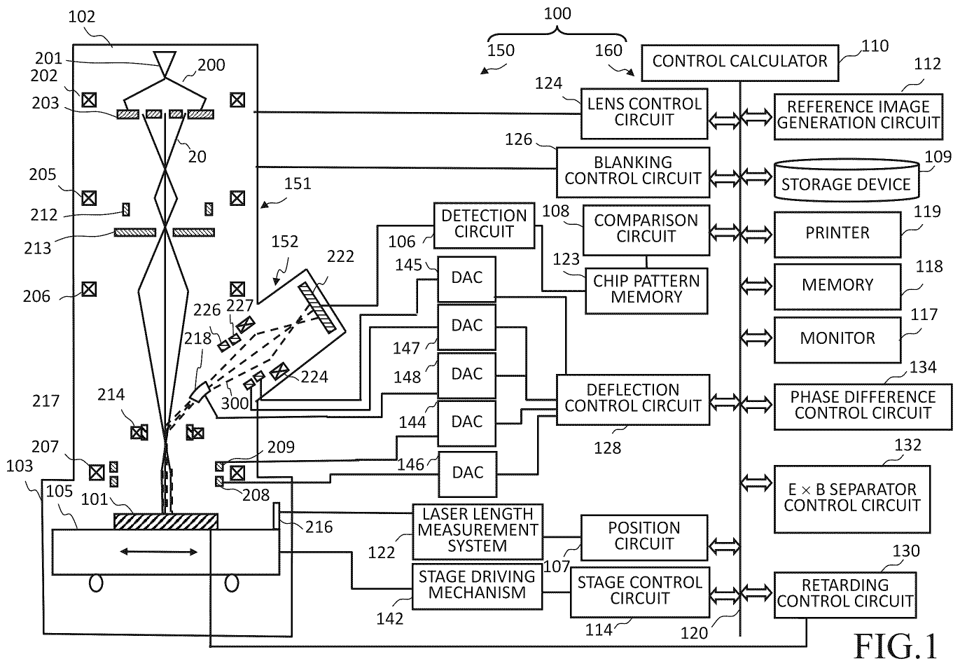

FIG. 1 is a configuration diagram showing the configuration of a pattern inspection apparatus according to Embodiment 1. In FIG. 1, an inspection apparatus 100 for inspecting a pattern formed on a substrate is an example of a multi-electron beam inspection apparatus. The inspection apparatus 100 is an example of a multi-electron beam image acquisition apparatus. The inspection apparatus 100 includes an image acquisition mechanism 150 and a control system circuit 160 (control unit). The image acquisition mechanism 150 includes an electron beam column 102 (electron optical column), an inspection room 103, a detection circuit 106, a chip pattern memory 123, a stage driving mechanism 142, and a laser length measurement system 122. An electron emission source 201, an electromagnetic lens 202, a shaping aperture array substrate 203, an electromagnetic lens 205, a collective deflector 212, a limited aperture substrate 213, an electromagnetic lens 206, an E×B separator 214 (separator), a plurality of deflectors 208 and 209 (first electrostatic deflector, first deflector) in two stages, an electromagnetic lens 207, a deflector 218, a plurality of deflectors 226 and 227 (second electrostatic deflector, second deflector) in two stages, an electromagnetic lens 224, and a multi-detector 222 are arranged in the electron beam column 102.

In addition, as the deflectors 208 and 209 (226 and 227), electrostatic deflectors having four or more poles or magnetic deflectors having four or more poles are used. In Embodiment 1, the deflectors 208 and 209 (226 and 227) will be described as electrostatic deflectors, for example.

The electron emission source 201, the electromagnetic lens 202, the shaping aperture array substrate 203, the electromagnetic lens 205, the collective deflector 212, the limited aperture substrate 213, the electromagnetic lens 206, the electromagnetic lens 207 (objective lens), and the two-stage deflectors 208 and 209 form a primary electron optics 151 (illumination optical system). In addition, the electromagnetic lens 207 (objective lens), the E×B separator 214, the deflector 218, the two-stage deflectors 226 and 227, and the electromagnetic lens 224 form a secondary electron optics 152 (detection optical system).

A stage 105 that can move at least in the X and Y directions is arranged in the inspection room 103. A substrate 101 (target object) to be inspected is arranged on the stage 105. Examples of the substrate 101 include an exposure mask substrate and a semiconductor substrate, such as a silicon wafer. When the substrate 101 is a semiconductor substrate, a plurality of chip patterns (wafer dies) are formed on the semiconductor substrate. When the substrate 101 is an exposure mask substrate, a chip pattern is formed on the exposure mask substrate. The chip pattern is formed by a plurality of figures. By exposing and transferring the chip pattern formed on the exposure mask substrate to the semiconductor substrate a plurality of times, a plurality of chip patterns (wafer dies) are formed on the semiconductor substrate. Hereinafter, a case where the substrate 101 is a semiconductor substrate will be mainly described. The substrate 101 is arranged on the stage 105, for example, with the pattern forming surface facing upward. In addition, a mirror 216 that reflects a laser beam for laser length measurement emitted from the laser length measurement system 122 arranged outside the inspection room 103 is arranged on the stage 105.

In addition, the multi-detector 222 is connected to the detection circuit 106 outside the electron beam column 102. The detection circuit 106 is connected to the chip pattern memory 123.

In the example of FIG. 1, a case is shown in which a plurality of deflectors 208 and 209 in two stages and a plurality of deflectors 226 and 227 in two stages are arranged. In the example of FIG. 1, the two-stage deflectors 208 and 209 are arranged between the E×B separator 214 and the electromagnetic lens 207 (objective lens). In addition, the two-stage deflectors 226 and 227 are arranged between the E×B separator 214 and the electromagnetic lens 224 (projection lens). More specifically, the two-stage deflectors 226 and 227 are arranged between the deflector 218 and the electromagnetic lens 224 (projection lens).

In the control system circuit 160, a control calculator 110 that controls the entire inspection apparatus 100 is connected to a position circuit 107, a comparison circuit 108, a reference image generation circuit 112, a stage control circuit 114, a lens control circuit 124, a blanking control circuit 126, a deflection control circuit 128, a retarding control circuit 130, an E×B separator control circuit 132, a phase difference control circuit 134, a storage device 109 such as a magnetic disk drive, a monitor 117, a memory 118, and a printer 119 through a bus 120. In addition, the deflection control circuit 128 is connected to DAC (digital-to-analog conversion) amplifiers 144, 145, 146, 147, and 148. The DAC amplifier 146 is connected to the deflector 208, and the DAC amplifier 144 is connected to the deflector 209. The DAC amplifier 148 is connected to the deflector 218. The DAC amplifier 145 is connected to the deflector 226, and the DAC amplifier 147 is connected to the deflector 227.

In addition, the chip pattern memory 123 is connected to the comparison circuit 108. In addition, the stage 105 is driven by the stage driving mechanism 142 under the control of the stage control circuit 114. In the stage driving mechanism 142, for example, a drive system such as a three-axis (X-Y-θ) motor for driving in the X, Y, and θ directions in the stage coordinate system is configured, so that the stage 105 can move in the X, Y, and θ directions. As these X motor, Y motor, and θ motor (not shown), for example, step motors can be used. The stage 105 can be moved in the horizontal direction and the rotational direction by a motor of each axis of X, Y, and θ. Then, the moving position of the stage 105 is measured by the laser length measurement system 122 and supplied to the position circuit 107. The laser length measurement system 122 measures the position of the stage 105 based on the principle of the laser interferometry by receiving light reflected from the mirror 216. In the stage coordinate system, for example, X, Y, and θ directions of the primary coordinate system are set with respect to the plane perpendicular to the optical axis of multiple primary electron beams 20.

The electromagnetic lens 202, the electromagnetic lens 205, the electromagnetic lens 206, the electromagnetic lens 207, and the electromagnetic lens 224 are controlled by the lens control circuit 124. In addition, the collective deflector 212 is formed by electrodes having two or more poles, and each electrode is controlled by the blanking control circuit 126 through a DAC amplifier (not shown). The deflector 209 is formed by electrodes having four or more poles, and each electrode is controlled by the deflection control circuit 128 through the DAC amplifier 144. The deflector 208 is formed by electrodes having four or more poles, and each electrode is controlled by the deflection control circuit 128 through the DAC amplifier 146. The deflector 218 is formed by two-stage deflectors formed by electrodes having four or more poles, and each electrode is controlled by the deflection control circuit 128 through the DAC amplifier 148. In addition, the deflector 226 is formed by electrodes having four or more poles, and each electrode is controlled by the deflection control circuit 128 through the DAC amplifier 145. In addition, the deflector 227 is formed by electrodes having four or more poles, and each electrode is controlled by the deflection control circuit 128 through the DAC amplifier 147. The retarding control circuit 130 (potential application circuit) applies a desired retarding potential to the substrate 101 to adjust the energy of the multiple primary electron beams 20 emitted to the substrate 101.

The E×B separator 214 is controlled by the E×B separator control circuit 132.

A high-voltage power supply circuit (not shown) is connected to the electron emission source 201, and a group of electrons emitted from the cathode are accelerated by the application of an acceleration voltage from the high-voltage power supply circuit between a filament and an extraction electrode (not shown) in the electron emission source 201, the application of a voltage to a predetermined extraction electrode (Wehnelt), and the heating of the cathode at a predetermined temperature, and emitted as an electron beam 200.

Here, FIG. 1 describes components necessary for explaining Embodiment 1. The inspection apparatus 100 may usually include other necessary components.

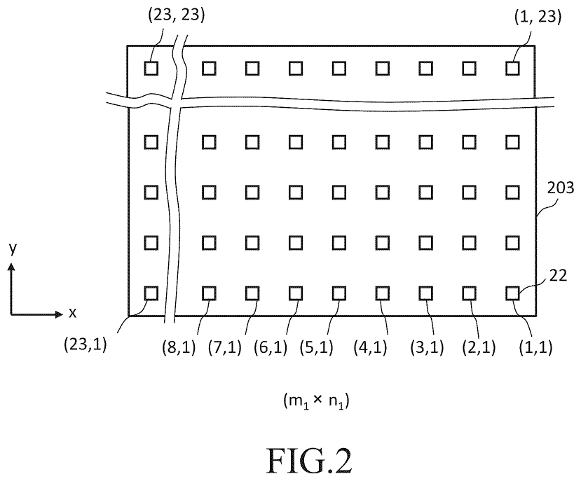

FIG. 2 is a conceptual diagram showing the configuration of a shaping aperture array substrate according to Embodiment 1. In FIG. 2, on the shaping aperture array substrate 203, two-dimensional width (x direction) m₁ columns×length (y direction) n₁ stages (m₁ and n₁ are integers of 2 or more) holes (openings) 22 are formed at predetermined arrangement pitches in the x and y directions. In the example of FIG. 2, a case where 23×23 holes (openings) 22 are formed is shown. The holes 22 are formed in rectangles having the same dimension and shape. Alternatively, the holes 22 may be circles having the same outer diameter. Some of the electron beams 200 pass through the plurality of holes 22 to form the multiple primary electron beams 20. The shaping aperture array substrate 203 is an example of a multi-beam forming mechanism for forming multiple primary electron beams.

The image acquisition mechanism 150 acquires an image to be inspected of a figure from the substrate 101 on which the figure is formed by using multiple beams using electron beams. Hereinafter, the operation of the image acquisition mechanism 150 in the inspection apparatus 100 will be described.

The electron beam 200 emitted from the electron emission source 201 (emission source) is refracted by the electromagnetic lens 202 to illuminate the entire shaping aperture array substrate 203. As shown in FIG. 2, a plurality of holes 22 (openings) are formed on the shaping aperture array substrate 203, and a region including all of the plurality of holes 22 is illuminated with the electron beam 200. Some of the electron beams 200 emitted to the positions of the plurality of holes 22 pass through the plurality of holes 22 on the shaping aperture array substrate 203 to form the multiple primary electron beams 20.

The formed multiple primary electron beams 20 are refracted by the electromagnetic lenses 205 and 206, and travel to the E×B separator 214 arranged at the intermediate field (field conjugate position: I. I. P.) of each of the multiple primary electron beams 20 while repeating an intermediate image and crossover. Then, the multiple primary electron beams 20 pass through the E×B separator 214 to travel to the electromagnetic lens 207. In addition, scattered beams can be shielded by arranging the limited aperture substrate 213 having a limited passage hole near the crossover position of the multiple primary electron beams 20. In addition, all of the multiple primary electron beams 20 can be blanked by collectively deflecting all of the multiple primary electron beams 20 with the collective deflector 212 and shielding all of the multiple primary electron beams 20 with the limited aperture substrate 213.

When the multiple primary electron beams 20 are incident on an electromagnetic lens 207 (objective lens), the electromagnetic lens 207 focuses the multiple primary electron beams 20 on the substrate 101. In other words, the electromagnetic lens 207 irradiates the substrate 101 with the multiple primary electron beams 20. In this manner, the primary electron optics 151 irradiates the substrate 101 with the multiple primary electron beams 20.

The multiple primary electron beams 20 focused on the surface of the substrate 101 (target object) by the objective lens 207 are collectively deflected by the deflectors 208 and 209, and are emitted to the irradiation position of each beam on the substrate 101. In this manner, the primary electron optics 151 irradiates the substrate 101 with the multiple primary electron beams 20.

When the multiple primary electron beams 20 are emitted to a desired position of the substrate 101, a group of secondary electrons (multiple secondary electron beams 300) including reflected electrons are emitted from the substrate 101 due to the emission of the multiple primary electron beams 20. A secondary electron beam corresponding to each beam of the multiple primary electron beams 20 is emitted.

The multiple secondary electron beams 300 emitted from the substrate 101 pass through the electromagnetic lens 207 to travel to the E×B separator 214.

The E×B separator 214 separates the multiple secondary electron beams 300 from the orbit of the multiple primary electron beams 20.

The E×B separator 214 has a plurality of magnetic poles (electromagnetic deflection coils) having four or more poles using coils and a plurality of electrodes (electrostatic deflection electrodes) having four or more poles. For example, a plurality of magnetic poles with a phase shift of 90° and a plurality of electrodes with a phase shift of 90° are arranged. In addition, a plurality of magnetic poles and a plurality of electrodes are alternately arranged with a phase shift of 45°. The arrangement method is not limited thereto. A plurality of magnetic poles and a plurality of electrodes may be arranged so as to overlap each other in the same phase. The E×B separator 214 deflects the multiple secondary electron beams 300 to cause a separation effect. The E×B separator 214 generates a directional magnetic field using a plurality of magnetic poles. Similarly, a directional electric field is generated by a plurality of electrodes. Specifically, the E×B separator 214 generates an electric field E and a magnetic field B so as to be perpendicular to each other on a plane perpendicular to a direction in which the central beam of the multiple primary electron beams 20 travels (central axis of the orbit). The electric field applies a force in the same direction regardless of the traveling direction of the electron. On the other hand, the magnetic field applies a force according to the Fleming's left-hand rule. Therefore, the direction of the force acting on the electron can be changed depending on the electron incidence direction. In the multiple primary electron beams 20 incident on the E×B separator 214 from above, a force FE due to the electric field and a force FB due to the magnetic field cancel each other out. Therefore, the multiple primary electron beams 20 travel straight downward. On the other hand, in the multiple secondary electron beams 300 incident on the E×B separator 214 from below, both the force FE due to the electric field and the force FB due to the magnetic field act in the same direction. Therefore, the multiple secondary electron beams 300 are bent obliquely upward by being deflected in a predetermined direction and separated from the orbit of the multiple primary electron beams 20.

The multiple secondary electron beams 300, which are bent obliquely upward and separated from the multiple primary electron beams 20, are guided to the multi-detector 222 by the secondary electron optics 152. Specifically, the multiple secondary electron beams 300 separated from the multiple primary electron beams 20 are further bent by being deflected by the deflector 218, and travel to the electromagnetic lens 224. Then, the multiple secondary electron beams 300 are projected onto the multi-detector 222 while being refracted in the focusing direction by the electromagnetic lens 224 at a position away from the orbit of the multiple primary electron beams 20. The multi-detector 222 (multiple secondary electron beams detector) detects the multiple secondary electron beams 300 separated from the orbit of the multiple primary electron beams 20. In other words, the multi-detector 222 detects the refracted and projected multiple secondary electron beams 300. The multi-detector 222 has a plurality of detection elements (for example, diode type two-dimensional sensors (not shown)). Then, each of the multiple primary electron beams 20 collides with a detection element corresponding to each of the multiple secondary electron beams 300 on the detection surface of the multi-detector 222 to generate electrons, thereby generating secondary electron image data for each pixel. The intensity signal detected by the multi-detector 222 is output to the detection circuit 106.

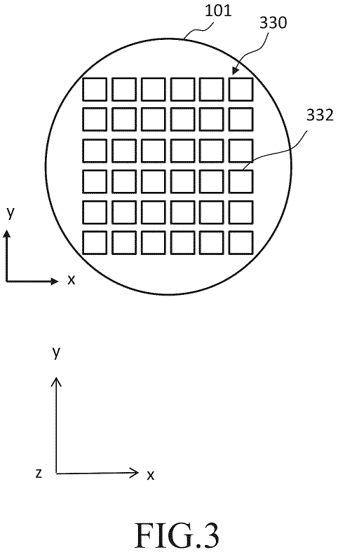

FIG. 3 is a diagram showing an example of a plurality of chip regions formed on a semiconductor substrate in Embodiment 1. In FIG. 3, a plurality of chips (wafer dies) 332 are formed in a two-dimensional array in an inspection region 330 of a semiconductor substrate (wafer) 101. A mask pattern for one chip formed on an exposure mask substrate is transferred onto each chip 332 so as to be reduced to, for example, ¼ by an exposure apparatus (stepper) (not shown).

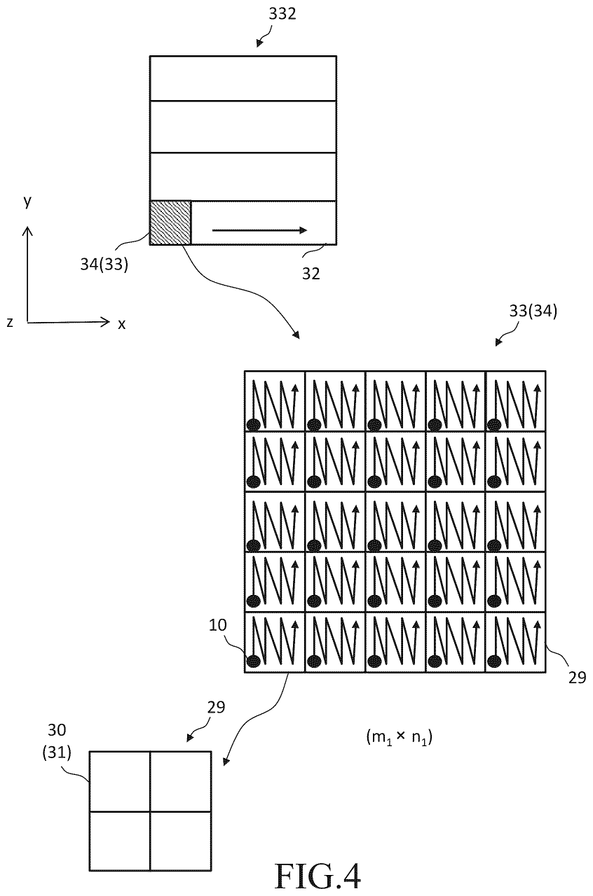

FIG. 4 is a diagram for explaining image acquisition processing in Embodiment 1. As shown in FIG. 4, the region of each chip 332 is divided into a plurality of stripe regions 32 with a predetermined width in the y direction, for example. The scanning operation of the image acquisition mechanism 150 is performed, for example, for each stripe region 32. For example, while moving the stage 105 in the −x direction, the scanning operation on the stripe region 32 is performed relatively in the x direction. Each stripe region 32 is divided into a plurality of rectangular regions 33 in the longitudinal direction. The movement of the beam to the target rectangular region 33 is performed by collective deflection of all of the multiple primary electron beams 20 by the two-stage deflectors 208 and 209.

In the example of FIG. 4, for example, a case of the multiple primary electron beams 20 of 5×5 columns is shown. An irradiation region 34 that can be irradiated by one emission of the multiple primary electron beams 20 is defined by (x-direction size obtained by multiplying the x-direction beam-to-beam pitch of the multiple primary electron beams 20 on the surface of the substrate 101 by the number of x-direction beams)×(y-direction size obtained by multiplying the y-direction beam-to-beam pitch of the multiple primary electron beams 20 on the surface of the substrate 101 by the number of y-direction beams). The irradiation region 34 is a field of view of the multiple primary electron beams 20. Then, each primary electron beam 10 forming the multiple primary electron beams 20 is emitted into a sub-irradiation region 29 surrounded with the x-direction beam-to-beam pitch and the y-direction beam-to-beam pitch in which the beam itself is located, thereby scanning (scanning operation) the inside of the sub-irradiation region 29. Each primary electron beam 10 is responsible for any of the sub-irradiation regions 29 that are different from each other. Then, each primary electron beam 10 is emitted to the same position in the corresponding sub-irradiation region 29. The two-stage deflectors 208 and 209 collectively deflect the multiple primary electron beams 20 to scan the surface of the substrate 101 on which patterns are formed with the multiple primary electron beams 20. In other words, the movement of the primary electron beam 10 in the sub-irradiation region 29 is performed by collectively deflecting all of the multiple primary electron beams 20 using the two-stage deflectors 208 and 209. This operation is repeated to sequentially irradiate the inside of one sub-irradiation region 29 with one primary electron beam 10.

It is preferable that the width of each stripe region 32 is set to a size similar to the y-direction size of the irradiation region 34 or a size reduced by the scan margin. In the example of FIG. 3, a case where the irradiation region 34 has the same size as the rectangular region 33 is shown. However, the invention is not limited thereto. The irradiation region 34 may be smaller than the rectangular region 33. Alternatively, the irradiation region 34 may be larger than the rectangular region 33. Then, each primary electron beam 10 forming the multiple primary electron beams 20 is emitted into the sub-irradiation region 29 where the beam itself is located, thereby scanning (scanning operation) the inside of the sub-irradiation region 29. Then, after the end of the scanning of one sub-irradiation region 29, the irradiation position is moved to the adjacent rectangular region 33 in the same stripe region 32 by collective deflection of all of the multiple primary electron beams 20 by the two-stage deflectors 208 and 209. This operation is repeated to irradiate the inside of the stripe region 32 in order. After the end of the scanning of one stripe region 32, the irradiation region 34 is moved to the next stripe region 32 by the movement of the stage 105 and/or collective deflection of all of the multiple primary electron beams 20 using the two-stage deflectors 208 and 209. As described above, by emitting each primary electron beam 10, the scanning operation for each sub-irradiation region 29 and the acquisition of a secondary electron image are performed. By combining the secondary electron images for the respective sub-irradiation regions 29, a secondary electron image of the rectangular region 33, a secondary electron image of the stripe region 32, or a secondary electron image of the chip 332 is formed. In addition, when actually performing image comparison, the sub-irradiation region 29 in each rectangular region 33 is further divided into a plurality of frame regions 30, and frame images 31 that are measurement images for the respective frame regions 30 are compared. In the example of FIG. 4, a case is shown in which the sub-irradiation region 29 scanned with one primary electron beam 10 is divided into four frame regions 30 that are formed by equally dividing the sub-irradiation region 29 in the x and y directions, for example.

Here, when the substrate 101 is irradiated with the multiple primary electron beams 20 while the stage 105 continuously moves, a tracking operation by collective deflection of the two-stage deflectors 208 and 209 is performed so that the irradiation position of the multiple primary electron beams 20 follows the movement of the stage 105. Therefore, the emission positions of the multiple secondary electron beams 300 change from moment to moment with respect to the central axis of the orbit of the multiple primary electron beams 20. Similarly, when scanning the inside of the sub-irradiation region 29, the emission position of each secondary electron beam changes from moment to moment in the sub-irradiation region 29. The two-stage deflectors 226 and 227 collectively deflect the multiple secondary electron beams 300 so that each secondary electron beam whose emission position has changed as described above is emitted into the corresponding detection region of the multi-detector 222. In other words, the two-stage deflectors 226 and 227 fix the positions of the multiple secondary electron beams 300 on the detection surface of the multi-detector 222, which change due to scanning using the multiple primary electron beams 20, by deflection back of the multiple secondary electron beams. As a result, each secondary electron beam can be detected by the corresponding detection element of the multi-detector 222.

Here, when scanning the substrate 101 with the multiple primary electron beams 20, for example, if the multiple primary electron beams 20 are collectively deflected by a single-stage deflector, an aberration corresponding to the amount of deflection occurs in the multiple primary electron beams 20. Examples of such an aberration include coma aberration, field curvature, astigmatism, and/or distortion. Among these aberrations, aberrations such as the field curvature, the astigmatism, and/or the distortion can be dynamically corrected by individually applying a potential to each electrode forming the deflector. However, it is difficult to dynamically correct the coma aberration. For this reason, two-stage deflectors are used.

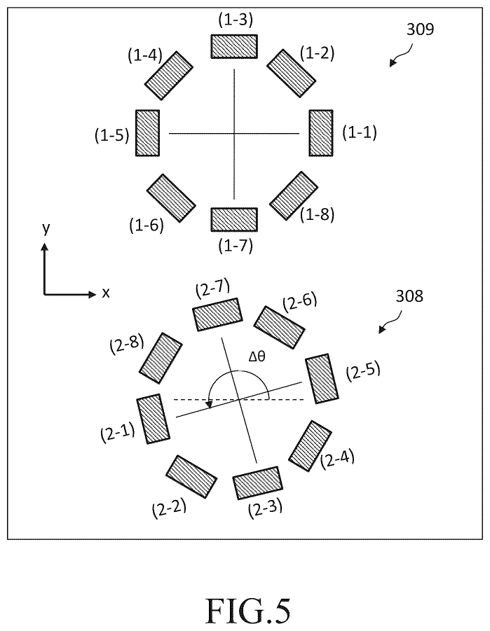

FIG. 5 is a top view showing an example of the arrangement of two-stage deflectors in a comparative example of Embodiment 1. In the comparative example of FIG. 5, a case is shown in which deflectors 309 and 308 in the respective stages are each configured by eight electrodes 1-1 (2-1) to 1-8 (2-8). In the comparative example of FIG. 5, the same potential is applied to the electrode in the first stage and the corresponding electrode in the second stage. For example, the same potential V1 is applied to the electrode 1-1 and the electrode 2-1. For example, the same potential V2 is applied to the electrode 1-2 and the electrode 2-2. For example, the same potential V3 is applied to the electrode 1-3 and the electrode 2-3. For example, the same potential V4 is applied to the electrode 1-4 and the electrode 2-4. For example, the same potential V5 is applied to the electrode 1-5 and the electrode 2-5. For example, the same potential V6 is applied to the electrode 1-6 and the electrode 2-6. For example, the same potential V7 is applied to the electrode 1-7 and the electrode 2-7. For example, the same potential V8 is applied to the electrode 1-8 and the electrode 2-8. In the comparative example, coma aberration occurring in the first-stage deflector 309 is corrected by the second-stage deflector 308. For this purpose, the second-stage deflector 308 is arranged with a phase shift of an angle Δθ with respect to the first-stage deflector 309, which minimizes the coma aberration. Thus, the method of correcting aberrations by mechanically shifting the phases of two-stage deflectors located up and down is effective when the energy state of the beam is uniquely determined as described above. However, when the energy state of the beam changes, the effective phase difference for correcting aberrations changes, making this method difficult to use. For example, when the landing energy of the electron beam onto the substrate is changed, the energy state of the beam changes. As a result, the effective phase difference Δθ for correcting aberrations changes. However, in image acquisition using an electron beam, there is an optimum landing energy depending on the yield of the substrate 101 to be inspected. For this reason, in the inspection apparatus 100, it is necessary to change the landing energy (L. E.) in accordance with the substrate 101 when capturing an image. Therefore, in Embodiment 1, the configuration is as follows.

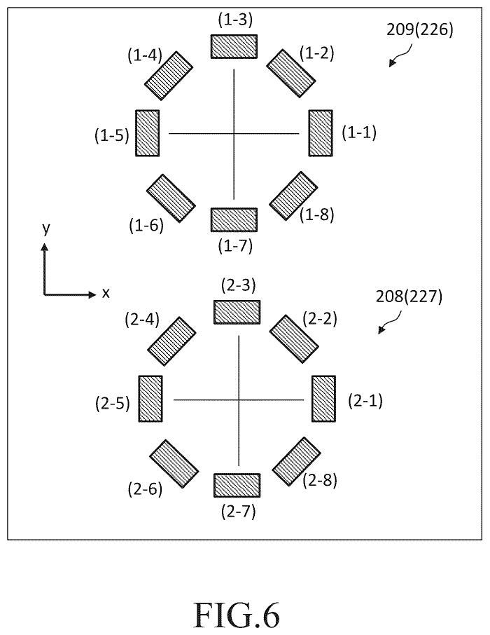

FIG. 6 is a top view showing an example of the arrangement of two-stage deflectors in Embodiment 1. In the example of FIG. 6, a case is shown in which deflectors 209 and 208 in the respective stages are each configured by eight electrodes 1-1 (2-1) to 1-8 (2-8). The plurality of deflectors 209 and 208 are arranged in the same phase. Then, in the example of FIG. 6, an individual potential corresponding to a phase difference Δθ in the deflection direction that reduces the aberration determined for each landing energy (L. E.) is applied to the electrode in the first stage and the corresponding electrode in the second stage.

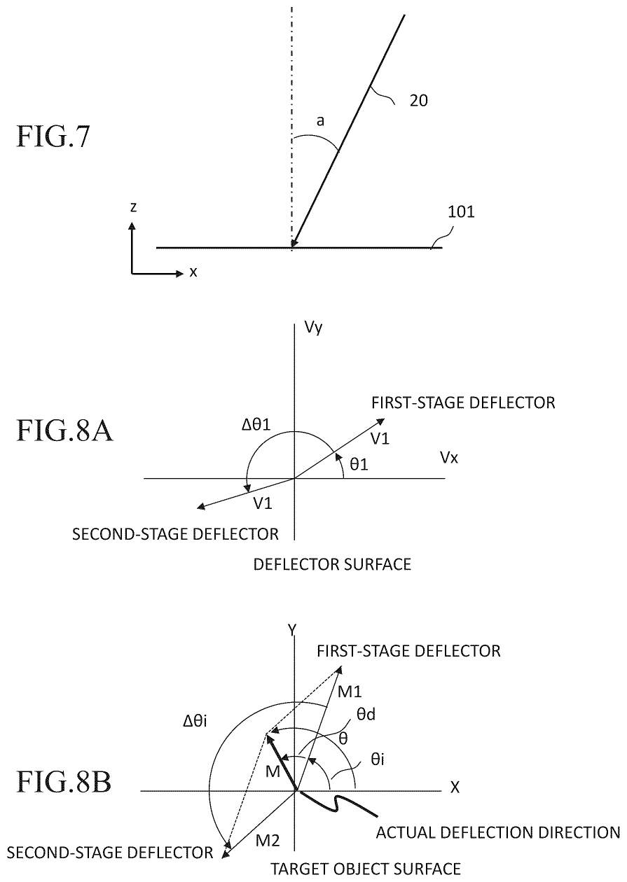

FIG. 7 is a diagram showing an example of the incidence angle of a beam in Embodiment 1. FIG. 7 shows a case where the multiple primary electron beams 20 are incident on the substrate 101 at an incidence angle a (opening angle). Here, the incidence angle a is shown as an incidence angle at the center of the orbit of the multiple primary electron beams 20. The coma aberration caused by beam deflection is proportional to a value obtained by multiplying the square of the incidence angle a by a deflection amount M. Coma aberration S1 caused by the first-stage deflector 209 can be defined by the following Equation (1) using the incidence angle a, a deflection amount M1 due to the first-stage deflector 209, and an aberration coefficient CC1.

$${S}_{1} = {CC}_{1} * {a}^{2} * {M}_{1} \qquad ( 1 )$$

Similarly, coma aberration S2 caused by the second-stage deflector 208 can be defined by the following Equation (2) using an incidence angle a2 due to the second-stage deflector 208, a deflection amount M2 due to the second-stage deflector 208, and an aberration coefficient CC2.

$${S}_{2} = {CC}_{2} * {a}^{2} * {M}_{2} \qquad ( 2 )$$

Here, as shown in the following Equation (3), a phase difference Δθ at which the sum of the aberrations of the first-stage deflector 209 and the second-stage deflector 208 becomes zero or minimal may be found.

$${S}_{1} + {S}_{2} = {CC}_{1} * {a}^{2} * {M}_{1} + {CC}_{2} * {a}^{2} * {M}_{2} = {a}^{2} ( {CC}_{1} * {M}_{1} + {CC}_{2} * {M}_{2} ) = 0 \qquad ( 3 )$$

Since the incidence angle a in Equation (3) is not zero during beam deflection, it is sufficient to find a phase difference Δθ1 on the deflector surface at which CC1 M1+CC2 M2=0 or minimum. The phase difference Δθ1 may be found by calculation in practice. Alternatively, a beam diameter for Δθ1 when the beam is deflected by the same amount may be found in advance, and Δθ1 may be found so that the beam diameter is minimized.

FIG. 8A is a diagram showing, by vectors, an example of the amount of deflection by a plurality of deflectors on a deflector surface in Embodiment 1. The respective arrangement height surfaces of the first-stage deflector 209 and the second-stage deflector 208 will be described as one deflector surface for convenience.

FIG. 8B is a diagram showing, by vectors, an example of the amount of deflection by a plurality of deflectors on a target object surface in Embodiment 1. On the target object surface, the beam is deflected in the direction and magnitude of a composite vector obtained by combining the two vectors shown in FIG. 8B. The first-stage deflector 209 is deflected in the direction of an angle θ1 with a potential V1, and the second-stage deflector 208 is deflected in the direction of an angle (θ1+Δθ1) with the potential V1. At this time, as shown in FIG. 8B, on the target object surface, the beam is deflected by the deflection amount M1 in the direction of an angle θi due to the deflection of the first-stage deflector 209, and is deflected by the deflection amount M2 in the direction of an angle (θi+Δθ i) due to the deflection of the second-stage deflector 208. The reason why the direction of voltage application on the deflector surface shown in FIG. 8A and the deflection direction on the target object surface shown in FIG. 8B are shifted by (θi−θ1) is that the electrons are rotated by the electromagnetic lens 207. In addition, the reason why the phase difference between the first-stage deflector 209 and the second-stage deflector 208 is not equal between the deflector surface and the target object surface is that the beam is rotated by the electromagnetic lens 207 by the height of the deflector. In the case of scanning, the potential V1 and the angle θ1 change from moment to moment according to the deflection amount and the deflection direction.

Assuming that the x-axis is 0°, the first-stage deflector 209 performs beam deflection indicated by a vector having the potential V1 in the direction of the angle θ1. Then, assuming that the x-axis is 0°, the second-stage deflector 208 performs beam deflection indicated by a vector having the potential V1 in the direction of the angle (θ1+Δθ1). As a result, on the target object surface, beam deflection of the multiple primary electron beams 20 is performed in the direction of the angle θ and the magnitude of the deflection amount M of a composite vector obtained by combining two vectors with the magnitude of the deflection amount M1 and the magnitude of the deflection amount M2 corresponding to these two vectors. If Δθ1 is set to a phase difference that makes the coma aberration be zero or minimal, it is possible to perform beam deflection with the coma aberration corrected to be zero or minimal.

In this case, a potential V11 applied to the electrode 1-1 of the first-stage deflector 209 can be defined by the following Equation (4-1). The potential V12 applied to the electrode 1-2 of the first-stage deflector 209 can be defined by the following Equation (4-2). The potential V13 applied to the electrode 1-3 of the first-stage deflector 209 can be defined by the following Equation (4-3). The potential V14 applied to the electrode 1-4 of the first-stage deflector 209 can be defined by the following Equation (4-4). The potential V15 applied to the electrode 1-5 of the first-stage deflector 209 can be defined by the following Equation (4-5). The potential V16 applied to the electrode 1-6 of the first-stage deflector 209 can be defined by the following Equation (4-6). The potential V17 applied to the electrode 1-7 of the first-stage deflector 209 can be defined by the following Equation (4-7). The potential V18 applied to the electrode 1-8 of the first-stage deflector 209 can be defined by the following Equation (4-8).

$${V}_{11} = {V}_{1} cos {θ}_{1} \qquad ( 4 - 1 )$$

$${V}_{12} = \frac{{V}_{11} + {V}_{13}}{\sqrt{2}} \qquad ( 4 - 2 )$$

$${V}_{13} = {V}_{1} sin {θ}_{1} \qquad ( 4 - 3 )$$

$${V}_{14} = \frac{- {V}_{11} + {V}_{13}}{\sqrt{2}} \qquad ( 4 - 4 )$$

$${V}_{15} = - {V}_{11} \qquad ( 4 - 5 )$$

$${V}_{16} = - {V}_{12} \qquad ( 4 - 6 )$$

$${V}_{17} = - {V}_{13} \qquad ( 4 - 7 )$$

$${V}_{18} = - {V}_{14} \qquad ( 4 - 8 )$$

On the other hand, the potential V21 applied to the electrode 2-1 of the second-stage deflector 208 can be defined by the following Equation (5-1). The potential V22 applied to the electrode 2-2 of the second-stage deflector 208 can be defined by the following Equation (5-2). The potential V23 applied to the electrode 2-3 of the second-stage deflector 208 can be defined by the following Equation (5-3). The potential V24 applied to the electrode 2-4 of the second-stage deflector 208 can be defined by the following Equation (5-4). The potential V25 applied to the electrode 2-5 of the second-stage deflector 208 can be defined by the following Equation (5-5). The potential V26 applied to the electrode 2-6 of the second-stage deflector 208 can be defined by the following Equation (5-6). The potential V27 applied to the electrode 2-7 of the second-stage deflector 208 can be defined by the following Equation (5-7). The potential V28 applied to the electrode 2-8 of the second-stage deflector 208 can be defined by the following Equation (5-8).

$${V}_{21} = {V}_{1} cos ( {θ}_{1} + {Δθ}_{1} ) \qquad ( 5 - 1 )$$

$${V}_{22} = \frac{{V}_{21} + {V}_{23}}{\sqrt{2}} \qquad ( 5 - 2 )$$

$${V}_{23} = {V}_{1} sin ( {θ}_{1} + {Δθ}_{1} ) \qquad ( 5 - 3 )$$

$${V}_{24} = \frac{- {V}_{21} + {V}_{23}}{\sqrt{2}} \qquad ( 5 - 4 )$$

$${V}_{25} = - {V}_{21} \qquad ( 5 - 5 )$$

$${V}_{26} = - {V}_{22} \qquad ( 5 - 6 )$$

$${V}_{27} = - {V}_{23} \qquad ( 5 - 7 )$$

$${V}_{28} = - {V}_{24} \qquad ( 5 - 8 )$$

As shown in FIG. 8A, when the first-stage deflector 209 is deflected in the direction of the angle θ1 with the potential V1 and the second-stage deflector 208 is deflected in the direction of the angle (θ1+Δθ1) with the potential V1, it is assumed that the amount of deflection on the target object surface is M, as shown in FIG. 8B. In this case, these relationships change proportionally. Therefore, for example, if the applied potential is doubled, the amount of deflection will also be doubled.

In addition, assuming that the amount of rotation of the beam deflection by the electromagnetic lens 207 is θm, the angle θi of the deflection direction of the first-stage deflector 209 on the target object surface shown in FIG. 8B can be defined as θi=θ1+θm. In addition, the angle θ, which is an actual deflection direction, is expressed as θ=θd+θi. In addition, Od is a deflection direction determined by the composite vector of the first-stage deflector 209 and the second-stage deflector 208. Therefore, θ=θd+θm+θ1. Since Od and θm are constants, the angle θ of the deflection direction is uniquely determined by θ1 of the first-stage deflector 209. If the deflection direction θ on the target object surface is measured in advance with respect to the command θ1 to the first-stage deflector 209, θd+θm can be measured as an offset component. In addition, the magnitude V1 of the potential is proportional to the distance from the center. The angle θ1 determines the angle θ of the deflection direction. This can be assigned to the drive voltages V11 to V18 and V21 to V28.

In addition, the above-described Equations (4-1) to (4-8) and Equations (5-1) to (5-8) show beam deflection for scanning using the multiple primary electron beams 20. In Embodiment 1, tracking control is further performed. In this case, Equations (4-1) to (4-8) and Equations (5-1) to (5-8) can be defined as Equations (6-1) to (6-8) and Equations (7-1) to (7-8).

$${V}_{11} = {V}_{1} cos {θ}_{1} + Vtr cos α \qquad ( 6 - 1 )$$

$${V}_{12} = \frac{{V}_{11} + {V}_{13}}{\sqrt{2}} \qquad ( 6 - 2 )$$

$${V}_{13} = {V}_{1} sin {θ}_{1} + Vtr sin α \qquad ( 6 - 3 )$$

$${V}_{14} = \frac{- {V}_{11} + {V}_{13}}{\sqrt{2}} \qquad ( 6 - 4 )$$

$${V}_{15} = - {V}_{11} \qquad ( 6 - 5 )$$

$${V}_{16} = - {V}_{12} \qquad ( 6 - 6 )$$

$${V}_{17} = - {V}_{13} \qquad ( 6 - 7 )$$

$${V}_{18} = - {V}_{14} \qquad ( 6 - 8 )$$

$${V}_{21} = {V}_{1} cos ( {θ}_{1} + {Δθ}_{1} ) + Vtr cos α \qquad ( 7 - 1 )$$

$${V}_{22} = \frac{{V}_{21} + {V}_{23}}{\sqrt{2}} \qquad ( 7 - 2 )$$

$${V}_{23} = {V}_{1} sin ( {θ}_{1} + {Δθ}_{1} ) + Vtr sin α \qquad ( 7 - 3 )$$

$${V}_{24} = \frac{- {V}_{21} + {V}_{23}}{\sqrt{2}} \qquad ( 7 - 4 )$$

$${V}_{25} = - {V}_{21} \qquad ( 7 - 5 )$$

$${V}_{26} = - {V}_{22} \qquad ( 7 - 6 )$$

$${V}_{27} = - {V}_{23} \qquad ( 7 - 7 )$$

$${V}_{28} = - {V}_{24} \qquad ( 7 - 8 )$$

First terms of Equations (6-1) and (6-3) and Equations (7-1) and (7-3) indicate beam deflection component terms for scanning using the multiple primary electron beams 20, and second terms indicate beam deflection component terms for tracking control. First terms of Equations (6-1) and (6-3) and Equations (7-1) and (7-3) are the same as those of Equations (4-1) and (4-3) and Equations (5-1) and (5-3).

For example, when performing correction in the X and Y directions as the amount of tracking movement, it is assumed that correction is required only for the potentials Vx and Vy based on the amount of correction and the deflection sensitivity. In this case, a tracking potential Vth and an angle α can be defined by the following Equations (8-1) and (8-2), respectively. A is a constant. The obtained potential Vth and angle α may be assigned to the second terms of Equations (6-1) and (6-3) and Equations (7-1) and (7-3).

$${V}_{tr} = \sqrt{{V}_{x}^{2} + {V}_{y}^{2}} \qquad ( 8 - 1 )$$

$$α = A tan ( {V}_{y} / {V}_{x} ) \qquad ( 8 - 2 )$$

In addition, the potential applied to each electrode of the deflector 209 and the potential applied to each electrode of the deflector 208 may be opposite. In other words, a deflector to which the potential considering the phase difference Δθ1 is applied may be the deflector 209 instead of the deflector 208.

Here, as described above, when the landing energy is changed, the phase difference Δθ1 that makes the coma aberration be zero or minimal changes. In Equation (3), the aberration coefficients CC1 and CC2 change. Therefore, in Embodiment 1, a relationship table between the landing energy and the phase difference Δθ1 that makes the coma aberration zero or minimal is created.

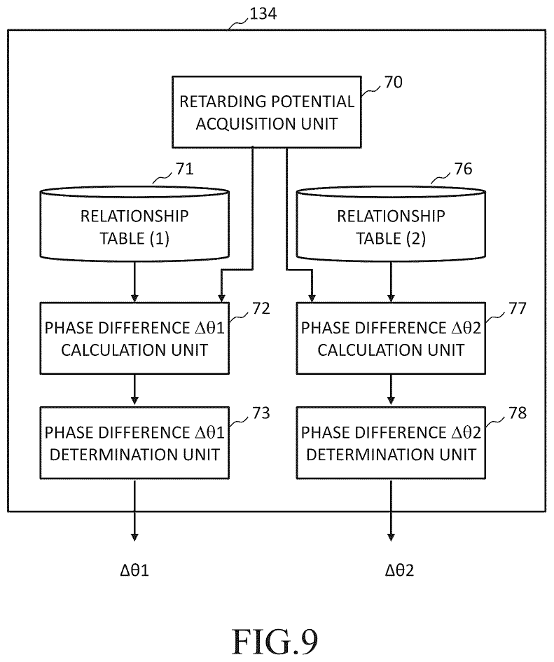

FIG. 9 is a block diagram showing an example of the internal configuration of a phase difference control circuit in Embodiment 1. In FIG. 9, storage devices 71 and 76 such as magnetic disk drives, a retarding potential acquisition unit 70, a phase difference calculation unit 72, a phase difference determination unit 73, a phase difference calculation unit 77, and a phase difference determination unit 78 are arranged in a phase difference control circuit 134. Each “unit”, such as the retarding potential acquisition unit 70, the phase difference calculation unit 72, the phase difference determination unit 73, the phase difference calculation unit 77, and the phase difference determination unit 78, has a processing circuit. Examples of such a processing circuit include an electrical circuit, a computer, a processor, a circuit board, a quantum circuit, and a semiconductor device. For each “unit”, a common processing circuit (the same processing circuit) may be used or different processing circuits (separate processing circuits) may be used. Information input to and output from the retarding potential acquisition unit 70, the phase difference calculation unit 72, the phase difference determination unit 73, the phase difference calculation unit 77, and the phase difference determination unit 78 and information being calculated are stored in the memory 118 or a memory (not shown) in the phase difference control circuit 134 each time.

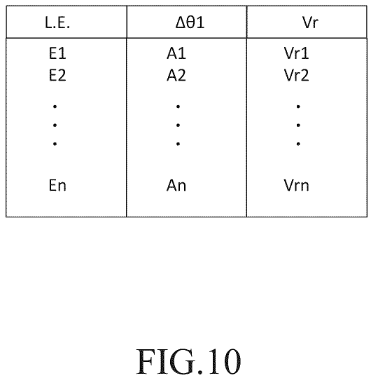

FIG. 10 is a diagram showing an example of a relationship table (1) showing a relationship among the landing energy, the phase difference, and the retarding potential associated with scanning using multiple primary electron beams in Embodiment 1. The landing energy (L. E.) can be defined as a value obtained by subtracting the energy Es that slows down the primary electrons due to the retarding potential applied to the target object surface from the energy Ea of the primary electrons due to the acceleration voltage, as shown in in the following Equation (9). In addition, Es can also be said to be the acceleration energy of the secondary electrons generated on the target object surface.

$$LE = Ea - Es \qquad ( 9 )$$

As shown in FIG. 10, in the relationship table (1), when the landing energy (L. E.) is E1, the phase difference Δθ1 is defined so as to correspond to A1, and the retarding potential Vr is defined so as to correspond to Vr1. When the landing energy (L. E.) is E2, the phase difference Δθ1 is defined so as to correspond to A2, and the retarding potential Vr is defined so as to correspond to Vr2. When the landing energy (L. E.) is En, the phase difference Δθ1 is defined so as to correspond to An, and the retarding potential Vr is defined so as to correspond to Vrn. Such a relationship may be found by simulation or experiment. Since the retarding potential is determined once the landing energy (L. E.) is determined, the relationship table may be a relationship table (1) showing the relationship between the phase difference Δθ1 and the retarding potential Vr, in which the landing energy (L. E.) is omitted. Such a relationship table (1) is stored in the storage device 109 or the storage device 71 in the phase difference control circuit 134.

If the relationship table (1) is stored in the storage device 109, the control calculator 110 reads the relationship table (1) from the storage device 109 and stores the relationship table (1) in the storage device 71 in the phase difference control circuit 134.

First, the retarding potential acquisition unit 70 acquires the retarding potential from a retarding control circuit 130.

The phase difference calculation unit 72 calculates the phase difference Δθ1 (first phase difference) of the deflection directions for the plurality of deflectors 208 and 209 so as to reduce the aberration caused by the deflection of the multiple primary electron beams according to the magnitude of the retarding potential. Then, the phase difference determination unit 73 (first determination unit) determines the phase difference of the deflection directions for the deflectors 209 and 208 to be the calculated phase difference Δθ 1. The determined phase difference Δθ1 is output to the deflection control circuit 128.

When acquiring an image, the deflection control circuit 128 applies individual potentials V11 to V18 and V21 to V28 corresponding to the determined phase difference Δθ1 (first phase difference) in the deflection direction to the respective electrodes of the plurality of deflectors 208 and 209. Then, as described above, the plurality of deflectors 208 and 209 collectively deflect the multiple primary electron beams 20, thereby scanning the substrate 101 placed on the stage 105 with the multiple primary electron beams 20.

Once the substrate 101 is scanned, a group of secondary electrons (multiple secondary electron beams 300) including reflected electrons are emitted from the substrate 101 due to the emission of the multiple primary electron beams 20. Then, the multiple secondary electron beams 300 are separated from the orbit of the multiple primary electron beams 20 by the E×B separator 214. Then, the separated multiple secondary electron beams 300 travel to the multi-detector 222 through the deflector 218 as described above.

Here, as described above, in order to project the multiple secondary electron beams 300, whose positions have been changed by scanning the substrate 101 with the multiple primary electron beams 20, onto each corresponding detection element of the multi-detector 222, the multiple secondary electron beams 300 are returned by the two-stage deflectors 226 and 227. In the case of return by a single-stage deflector, aberration according to the amount of deflection may occur in the multiple secondary electron beams 300. Examples of such an aberration include coma aberration, field curvature, astigmatism, and/or distortion. Among these aberrations, aberrations such as the field curvature, the astigmatism, and/or the distortion can be dynamically corrected by individually applying a potential to each electrode forming the deflector. However, it is difficult to dynamically correct the coma aberration. For this reason, in Embodiment 1, two-stage deflectors 226 and 227 are used. The two-stage deflectors 226 and 227 are arranged in the same phase, similarly to the deflectors 208 and 209.

In the case of returning the multiple secondary electron beams 300, beam deflection is performed in the direction of an angle θ′ and the magnitude of a deflection amount M′ of a composite vector obtained by combining two vectors on the surface of the multi-detector 222 due to the beam deflections of the two-stage deflectors 226 and 227, similarly to the case of scanning using the multiple primary electron beams 20. In addition, a phase difference Δθ2 between the first-stage deflector 226 and the second-stage deflector 227 is found in advance, similarly to the case of scanning using the multiple primary electron beams 20.

The first-stage deflector 226 is deflected in the direction of the angle θ2 with the potential V2, and the second-stage deflector 227 is deflected in the direction of an angle (θ2+Δθ2) with the potential V2. At this time, on the multi-detector surface, the beam is deflected by a deflection amount M1′ in the direction of an angle θj by the deflection of the first-stage deflector 226, and is deflected by a deflection amount M2′ in the direction of an angle (θj+Δθ j) by the deflection of the second-stage deflector 227. The reason why the direction of voltage application on the deflector surface and the deflection direction on the detector surface are shifted (θj−θ2) is due to rotation by the electromagnetic lens 224. In addition, the reason why the phase difference Δθ2 between the first-stage deflector 226 and the second-stage deflector 227 is not equal on the deflector surface and the multi-detector surface is that the beam is rotated by the electromagnetic lens 224 by the distance between the deflector and the electromagnetic lens 224. When performing deflection back, the potential V2 and the angle θ2 change from moment to moment according to the deflection amount and the deflection direction.

Assuming that the x-axis of the secondary beam coordinate system is 0°, the first-stage deflector 226 performs beam deflection indicated by a vector having a magnitude V2 in the direction of the angle θ2. Then, assuming that the x-axis of the secondary beam coordinate system is 0°, the second-stage deflector 227 performs beam deflection indicated by a vector having a magnitude V2 in the direction of the angle (θ2+Δθ2). As a result, on the surface of the multi-detector 222, beam deflection of the multiple secondary electron beams 300 is performed in the direction of the angle θ′ and the magnitude of the deflection amount M′ of a composite vector obtained by combining two vectors with the magnitude of the deflection amount M1′ and the magnitude of the deflection amount M2′ corresponding to these two vectors. If Δθ2 is set to a phase difference that makes the coma aberration be zero or minimal, it is possible to perform beam deflection with the coma aberration corrected to be zero or minimal.

In this case, the potential V31 applied to the electrode 3-1 of the first-stage deflector 226 can be defined by the following Equation (10-1). The potential V32 applied to the electrode 3-2 of the first-stage deflector 226 can be defined by the following Equation (10-2). The potential V33 applied to the electrode 3-3 of the first-stage deflector 226 can be defined by the following Equation (10-3). The potential V34 applied to the electrode 3-4 of the first-stage deflector 226 can be defined by the following Equation (10-4). The potential V35 applied to the electrode 3-5 of the first-stage deflector 226 can be defined by the following Equation (10-5). The potential V36 applied to the electrode 3-6 of the first-stage deflector 226 can be defined by the following Equation (10-6). The potential V37 applied to the electrode 3-7 of the first-stage deflector 226 can be defined by the following Equation (10-7). The potential V38 applied to the electrode 3-8 of the first-stage deflector 226 can be defined by the following Equation (10-8).

$${V}_{31} = {V}_{2} cos {θ}_{2} \qquad ( 10 - 1 )$$

$${V}_{32} = \frac{{V}_{31} + {V}_{33}}{\sqrt{2}} \qquad ( 10 - 2 )$$

$${V}_{33} = {V}_{2} sin {θ}_{2} \qquad ( 10 - 3 )$$

$${V}_{34} = \frac{- {V}_{31} + {V}_{33}}{\sqrt{2}} \qquad ( 10 - 4 )$$

$${V}_{35} = - {V}_{31} \qquad ( 10 - 5 )$$

$${V}_{36} = - {V}_{32} \qquad ( 10 - 6 )$$

$${V}_{37} = - {V}_{33} \qquad ( 10 - 7 )$$

$${V}_{38} = - {V}_{34} \qquad ( 10 - 8 )$$

On the other hand, the potential V41 applied to the electrode 4-1 of the second-stage deflector 227 can be defined by the following Equation (11-1). The potential V42 applied to the electrode 4-2 of the second-stage deflector 227 can be defined by the following Equation (11-2). The potential V43 applied to the electrode 4-3 of the second-stage deflector 227 can be defined by the following Equation (11-3). The potential V44 applied to the electrode 4-4 of the second-stage deflector 227 can be defined by the following Equation (11-4). The potential V45 applied to the electrode 4-5 of the second-stage deflector 227 can be defined by the following Equation (11-5). The potential V46 applied to the electrode 4-6 of the second-stage deflector 227 can be defined by the following Equation (11-6). The potential V47 applied to the electrode 4-7 of the second-stage deflector 227 can be defined by the following Equation (11-7). The potential V48 applied to the electrode 4-8 of the second-stage deflector 227 can be defined by the following Equation (11-8).

$${V}_{41} = {V}_{2} cos ( {θ}_{2} + {Δθ}_{2} ) \qquad ( 11 - 1 )$$

$${V}_{42} = \frac{{V}_{41} + {V}_{43}}{\sqrt{2}} \qquad ( 11 - 2 )$$

$${V}_{43} = {V}_{2} sin ( {θ}_{2} + {Δθ}_{2} ) \qquad ( 11 - 3 )$$

$${V}_{44} = \frac{- {V}_{41} + {V}_{43}}{\sqrt{2}} \qquad ( 11 - 4 )$$

$${V}_{45} = - {V}_{41} \qquad ( 11 - 5 )$$

$${V}_{46} = - {V}_{42} \qquad ( 11 - 6 )$$

$${V}_{47} = - {V}_{43} \qquad ( 11 - 7 )$$

$${V}_{48} = - {V}_{44} \qquad ( 11 - 8 )$$

Here, similarly to the case of scanning using the multiple primary electron beams 20, the magnitude V2 of the voltage is proportional to the distance from the center. θ2 determines the angle θ′ of the deflection direction. This may be assigned to the drive voltages V31 to V38 and V41 to V48.

In addition, the potential applied to each electrode of the deflector 226 and the potential applied to each electrode of the deflector 227 may be opposite. In other words, a deflector to which the potential considering the phase difference Δθ2 is applied may be the deflector 226 instead of the deflector 227.

Here, when the landing energy is changed, the energy state of the multiple secondary electron beams 300 changes. As a result, when the landing energy is changed, the phase difference Δθ2 that makes the coma aberration be zero or minimal changes. Therefore, in Embodiment 1, a relationship table between the landing energy and the phase difference Δθ2 that makes the coma aberration zero or minimal is created.

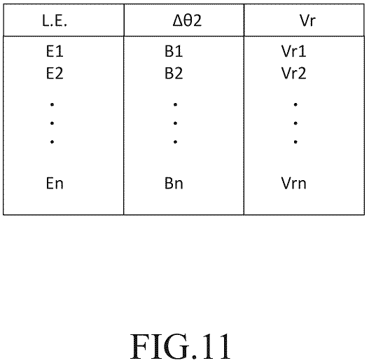

FIG. 11 is a diagram showing an example of a relationship table (2) showing a relationship between the landing energy, the phase difference, and the retarding potential associated with deflection back using multiple secondary electron beams in Embodiment 1.

As shown in FIG. 11, in the relationship table (2), when the landing energy (L. E.) is E1, the phase difference Δθ2 is defined so as to correspond to B1, and the retarding potential Vr is defined so as to correspond to Vr1. When the landing energy (L. E.) is E2, the phase difference Δθ2 is defined so as to correspond to B2, and the retarding potential Vr is defined so as to correspond to Vr2. When the landing energy (L. E.) is En, the phase difference Δθ2 is defined so as to correspond to Bn, and the retarding potential Vr is defined so as to correspond to Vrn. Such a relationship may be found by simulation or experiment. Since the retarding potential is determined once the landing energy (L. E.) is determined, the relationship table (2) may be a relationship table showing the relationship between the phase difference Δθ2 and the retarding potential Vr, in which the landing energy (L. E.) is omitted. Such a relationship table (2) is stored in the storage device 109 or the storage device 76 in the phase difference control circuit 134.

If the relationship table (2) is stored in the storage device 109, the control calculator 110 reads the relationship table (2) from the storage device 109 and stores the relationship table (2) in the storage device 76 in the phase difference control circuit 134.

The phase difference calculation unit 77 calculates the phase difference Δθ2 (second phase difference) of the deflection directions for the plurality of deflectors 226 and 227 (second deflectors) so as to reduce the aberration caused by the deflection of the multiple secondary electron beams 300 according to the magnitude of the retarding potential. Then, the phase difference determination unit 78 (second determination unit) determines the phase difference of the deflection directions for the deflectors 226 and 227 to be the calculated phase difference Δθ2. The determined phase difference Δθ2 is output to the deflection control circuit 128.

When acquiring an image, the deflection control circuit 128 further applies individual potentials V31 to V38 and V41 to V48 corresponding to the phase difference Δθ2 (second phase difference) in the deflection direction to the respective electrodes of the plurality of deflectors 226 and 227. Then, as described above, the plurality of deflectors 226 and 227 fix the positions where the multiple secondary electron beams 300 are projected onto the multi-detector 222 even when performing scanning using the multiple primary electron beams 20 by deflecting the multiple secondary electron beams 300 collectively so that the multiple secondary electron beams 300 are returned.

In this manner, each of the secondary electron beams can be detected by the corresponding detection element of the multi-detector 222.

As described above, the image acquisition mechanism 150 performs the scanning operation for each stripe region 32. As described above, the multiple primary electron beams 20 are emitted, and the multiple secondary electron beams 300 emitted from the substrate 101 due to the emission of the multiple primary electron beams 20 form an intermediate field (second field) in the deflector 218 and at the same time, are deflected by the deflector 218 and then detected by the multi-detector 222. The detected multiple secondary electron beams 300 may include reflected electrons. Alternatively, the reflected electrons may diverge while moving through the secondary electron optics and may not reach the multi-detector 222. Then, secondary electron images based on the signals of the detected multiple secondary electron beams 300 are acquired. Specifically, detection data (measurement image data, secondary electron image data, or inspected image data) of the secondary electrons for each pixel in each sub-irradiation region 29 detected by the multi-detector 222 is output to the detection circuit 106 in the order of measurement. In the detection circuit 106, analog detection data is converted into digital data by an A/D converter (not shown) and stored in the chip pattern memory 123. Then, the obtained measurement image data is transmitted to the comparison circuit 108 together with information indicating each position from the position circuit 107.

On the other hand, the reference image generation circuit 112 generates a reference image corresponding to the frame image 31 for each frame region 30 based on design data that is the basis of a plurality of figures formed on the substrate 101. Specifically, the reference image generation circuit 112 operates as follows. First, design pattern data is read out from the storage device 109 through the control calculator 110, and each figure defined in the read design pattern data is converted into binary or multi-valued image data.

As described above, the figures defined in the design pattern data include, for example, a basic figure of a rectangle or a triangle. For example, figure data is stored in which the shape, size, position, and the like of each figure are defined by information such as the coordinates (x, y) at the reference position of the figure, the length of the side, and a figure code that serves as an identifier for identifying the figure type such as a rectangle or a triangle.

When the design pattern data that serves as the figure data is input to the reference image generation circuit 112, the design pattern data is expanded to data for each figure, and the figure code, the figure dimension, and the like indicating the figure shape of the figure data are analyzed. Then, this is expanded into binary or multi-valued design pattern image data as a pattern arranged in a square having a grid with a predetermined quantization dimension as a unit, and is output. In other words, the design data is read, the occupancy rate of the figure in the design pattern is calculated for each square created by virtually dividing the inspection region into squares each having a predetermined dimension as a unit, and n-bit occupancy rate data is output. For example, it is preferable to set one square as one pixel. Then, assuming that one pixel has a resolution of ½⁸ (= 1/256), a small region of 1/256 is allocated to the region of the figure arranged in the pixel and the occupancy rate in the pixel is calculated. Then, 8-bit occupancy rate data is obtained. Such a square (inspection pixel) may be matched with each pixel of the measurement data.

Then, the reference image generation circuit 112 performs filtering processing on the design image data of the design pattern, which is the image data of the figure, by using a predetermined filter function. In this manner, the design image data whose image intensity (shade value) is image data on the design side of the digital value can be matched with image generation characteristics obtained by emission of the multiple primary electron beams 20. The image data for each pixel of the generated reference image is output to the comparison circuit 108.

The comparison circuit 108 aligns the frame image 31 (first image) serving as an image to be inspected and the reference image (second image) corresponding to the frame image in units of sub-pixels for each frame region 30. For example, the alignment may be performed using the method of least squares.

Then, the comparison circuit 108 compares the frame image 31 (first image) with the reference image (second image). The comparison circuit 108 compares the frame image 31 (first image) with the reference image (second image) for each pixel 36 according to a predetermined determination condition. For example, the comparison circuit 108 determines whether or not there is a defect, such as a shape defect. For example, if the gradation value difference for each pixel 36 is larger than a determination threshold value Th, it is determined that there is a defect. Then, the comparison result is output. The comparison result may be output to the storage device 109, the monitor 117, or the memory 118, or may be output through the printer 119.

In addition to the die database inspection described above, it is also preferable to perform a die-die inspection in which pieces of measurement image data obtained by imaging the same pattern at different locations on the same substrate are compared with each other. Alternatively, the inspection may be performed using only the self-measured image.

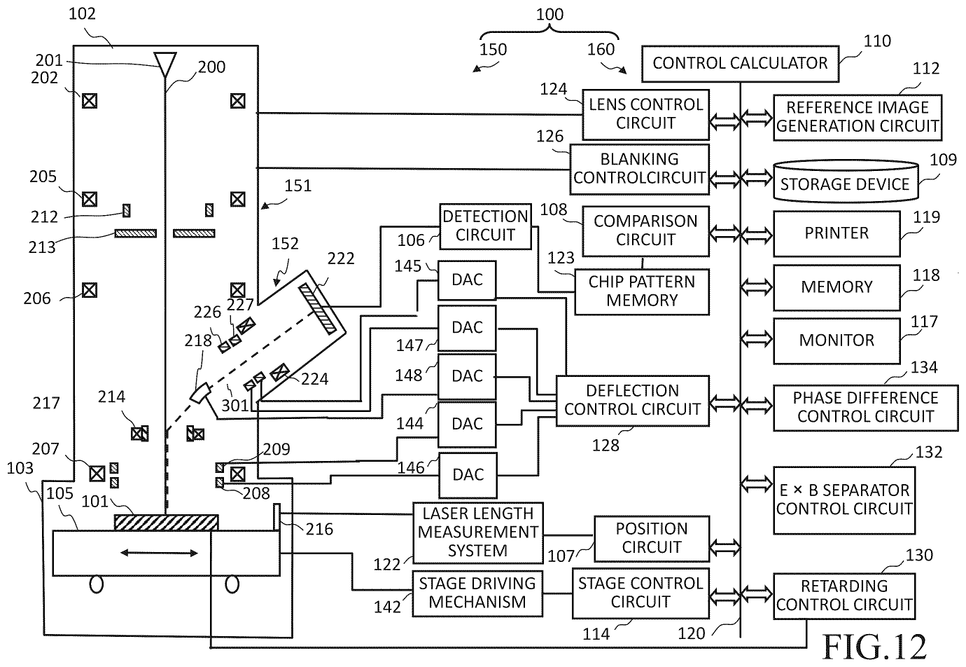

FIG. 12 is a configuration diagram showing the configuration of a pattern inspection apparatus according to Modification Example 1 of Embodiment 1. FIG. 12 is the same as FIG. 1 except that the shaping aperture array substrate 203 is omitted. In Modification Example 1 of Embodiment 1, since there is no shaping aperture array substrate 203, the multiple primary electron beams 20 are not formed. Therefore, a single primary electron beam 200 travels directly to the electromagnetic lens 205 side, and the substrate 101 is scanned with the single primary electron beam 200 by beam deflection of the single primary electron beam 200 due to the two-stage deflectors 208 and 209.

Alternatively, in addition to the configuration of FIG. 1, a beam selection aperture plate (not shown) that transmits only one beam and blocks the remaining beams may be arranged in front of or behind the shaping aperture array substrate 203 to generate one primary electron beam among the multiple primary electron beams 20. The control content of the deflectors 208 and 209 (226 and 227) is the same as that described above. The other contents are the same as those described above.

In this manner, the invention can be similarly applied not only to the case where multiple electron beams are used but also to the case where a single electron beam is used.

In the above example, a deflection angle V_{U1} serving as a reference voltage to be applied to the first-stage deflector 209 and a deflection angle V_{L1} serving as a reference voltage to be applied to the second-stage deflector 209 are both set as V1 and used in Equations (4-1) to (4-8) and Equations (5-1) to (5-8) (Equations (6-1) to (6-8) and Equations (7-1) to (7-8)), but the invention is not limited thereto. Hereinafter, this will be described as Modification Example 2 of Embodiment 1. In Modification Example 2 of Embodiment 1, either multiple beams or a single beam may be used. Therefore, the configuration of the inspection apparatus 100 is the same as that shown in FIG. 1 or 12. In addition, the two-stage deflectors may be either electrostatic deflectors or magnetic deflectors.

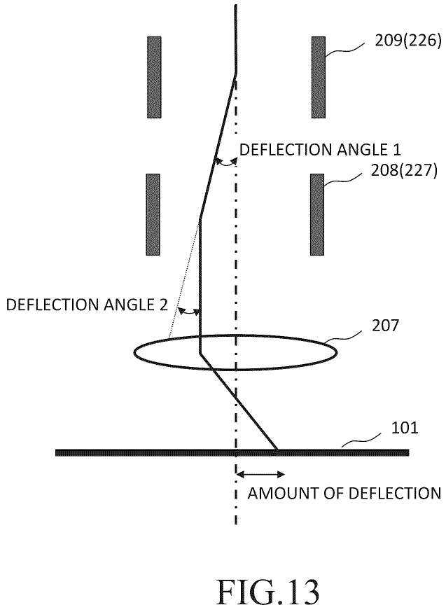

FIG. 13 is a diagram for explaining the deflection angles of two-stage deflectors in Modification Example 2 of Embodiment 1. FIG. 13 shows an example of how the electron beam is deflected by the two-stage deflectors 208 and 209 and the primary electron beam 200 is imaged on the substrate 101 by the electromagnetic lens 207. In FIG. 13, an angle at which the first-stage deflector 209 deflects is the deflection angle V_{U1} (deflection angle 1). In addition, an angle at which the second-stage deflector 208 deflects is the deflection angle V_{L1} (deflection angle 2).

The deflection angles 1 and 2 correspond to voltage in the case of an electrostatic deflector, and correspond to current flowing through a coil in the case of a magnetic deflector.

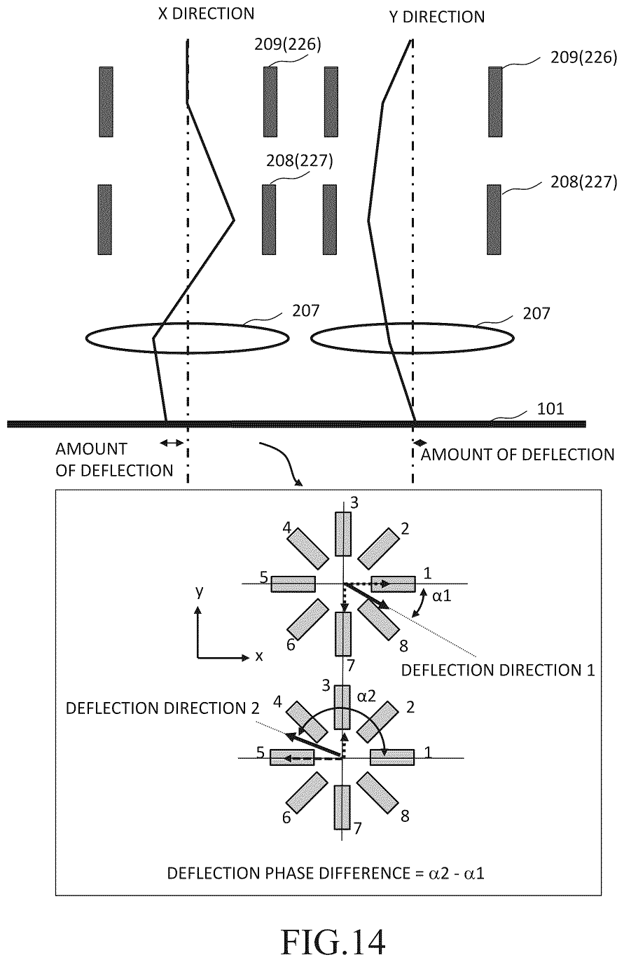

FIG. 14 is a diagram for explaining the phase difference between two-stage deflectors in Modification Example 2 of Embodiment 1. In the example of FIG. 14, the first-stage deflector 209 deflects the electron beam in the deflection direction 1 which is a combination of the +x direction and the −y direction. Then, the second-stage deflector 208 deflects the electron beam in the deflection direction 2 which is a combination of the −x direction and the +y direction. In this case, a difference (α2−α1) between, for example, a phase angle α1 from the x-axis as a reference axis to the deflection direction 1 and a phase angle α2 from the x-axis to the deflection direction 2 is a deflection phase difference.

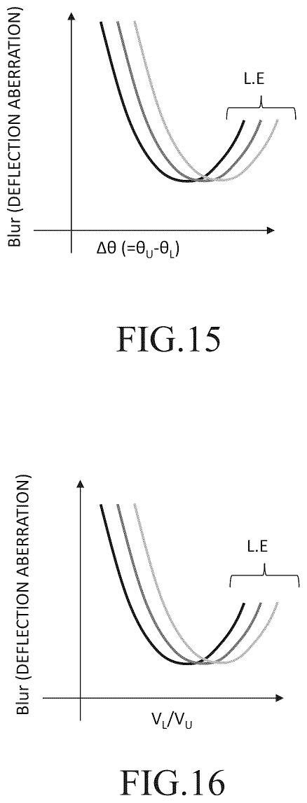

FIG. 15 is a diagram showing an example of the relationship among landing energy, deflection aberration, and phase difference in Modification Example 2 of Embodiment 1. In FIG. 15, the vertical axis indicates the deflection aberration. The horizontal axis indicates the phase difference Δθ (deflection phase difference). In the example of FIG. 15, a relationship between the deflection aberration and the deflection phase difference for each landing energy L. E. is shown.

FIG. 16 is a diagram showing an example of the relationship among landing energy, deflection aberration, and deflection angle ratio in Modification Example 2 of Embodiment 1. In FIG. 16, the vertical axis indicates the deflection aberration. The horizontal axis indicates the deflection angle ratio (V_{L}/V_{U}) (voltage ratio) between the deflection angle V_{U} of the first-stage deflector and the deflection angle V_{L} of the second-stage deflector. In the example of FIG. 16, the relationship between the deflection aberration and the deflection angle ratio for each landing energy L. E. is shown.

As shown in FIGS. 15 and 16, it can be seen that the aberration changes depending on the deflection phase difference Δθ and/or the deflection angle ratio (V_{L}/V_{U}) for each landing energy L. E. Therefore, in each embodiment, both the deflection angle V_{U1} and the deflection angle V_{L1} used for scanning using a primary electron beam are not limited to being V1 for deflection angle ratio=1, but may be set differently.

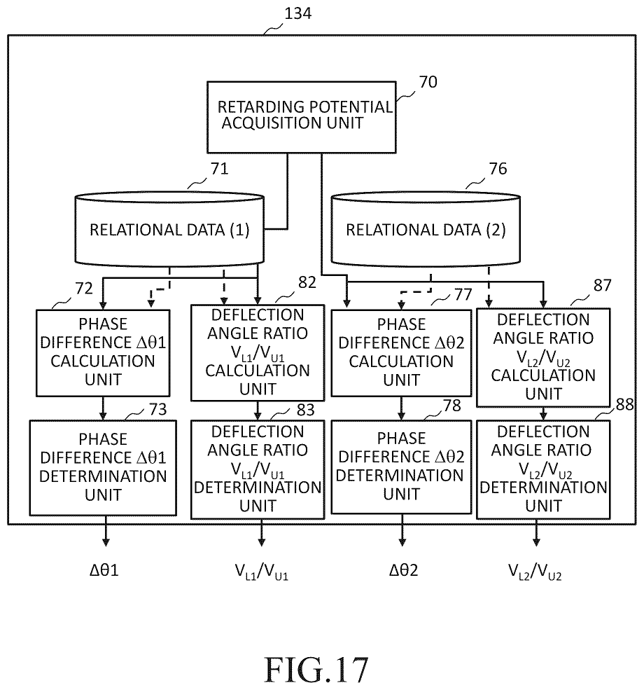

FIG. 17 is a diagram showing another example of the internal configuration of the phase difference calculation circuit in Modification Example 2 of Embodiment 1. FIG. 17 is the same as FIG. 9 except that a deflection angle ratio calculation unit 82, a deflection angle ratio determination unit 83, a deflection angle ratio calculation unit 87, and a deflection angle ratio determination unit 88 are further added within the phase difference control circuit 134.

Each “unit”, such as the retarding potential acquisition unit 70, the phase difference calculation unit 72, the phase difference determination unit 73, the phase difference calculation unit 77, the phase difference determination unit 78, the deflection angle ratio calculation unit 82, the deflection angle ratio determination unit 83, the deflection angle ratio calculation unit 87, and the deflection angle ratio determination unit 88, has a processing circuit. Examples of such a processing circuit include an electrical circuit, a computer, a processor, a circuit board, a quantum circuit, or a semiconductor device. For each “unit”, a common processing circuit (the same processing circuit) may be used or different processing circuits (separate processing circuits) may be used. Information input to and output from the retarding potential acquisition unit 70, the phase difference calculation unit 72, the phase difference determination unit 73, the phase difference calculation unit 77, the phase difference determination unit 78, the deflection angle ratio calculation unit 82, the deflection angle ratio determination unit 83, the deflection angle ratio calculation unit 87, and the deflection angle ratio determination unit 88 and information being calculated are stored in the memory 118 or a memory (not shown) in the phase difference control circuit 134 each time.

In addition, the storage device 71 stores relational data (1) indicating the relationship among the landing energy, deflection aberration and phase difference for the primary electron beam and the relationship among the landing energy, deflection aberration, and deflection angle ratio. The storage device 76 stores relational data (2) indicating the relationship among the landing energy, deflection aberration, and phase difference for the secondary electron beam and the relationship among the landing energy, deflection aberration, and deflection angle ratio.

As described above, if one of the landing energy (L. E.) and the retarding potential is determined, the other is also determined.

First, the retarding potential acquisition unit 70 acquires a retarding potential from the retarding control circuit 130.

Referring to the relational data (1), the phase difference calculation unit 72 calculates a deflection phase difference Δθ1 for the two-stage deflectors 208 and 209, at which the deflection aberration becomes equal to or less than a threshold value set in advance, according to the magnitude of the retarding potential applied to the substrate 101. Then, the phase difference determination unit 73 (first determination unit) determines the phase difference of the deflection directions for the two-stage deflectors 209 and 208 to be the calculated phase difference Δθ 1. The determined phase difference Δθ1 is output to the deflection control circuit 128.

And/or, referring to the relational data (1), the deflection angle ratio calculation unit 82 calculates a deflection angle ratio V_{L1}/V_{U1} for the two-stage deflectors 208 and 209, at which the deflection aberration becomes equal to or less than a threshold value set in advance, according to the magnitude of the retarding potential applied to the substrate 101. Then, the deflection angle ratio determination unit 83 determines the deflection angle ratio for the two-stage deflectors 209, 208 to be the calculated deflection angle ratio V_{L1}/V_{U1}. The determined deflection angle ratio V_{L1}/V_{U1} is output to the deflection control circuit 128.

In addition, referring to the relational data (2), the phase difference calculation unit 77 calculates a deflection phase difference Δθ2 for the two-stage deflectors 226 and 227, at which the deflection aberration becomes equal to or less than a threshold value set in advance, according to the magnitude of the retarding potential applied to the substrate 101. Then, the phase difference determination unit 78 (second determination section) determines the phase difference of the deflection directions for the two-stage deflectors 226 and 227 to be the calculated phase difference Δθ2. The determined phase difference Δθ2 is output to the deflection control circuit 128.

And/or, referring to the relational data (2), the deflection angle ratio calculation unit 87 calculates a deflection angle ratio V_{L2}/V_{U2} for the two-stage deflectors 226 and 227, at which the deflection aberration becomes equal to or less than a threshold value set in advance, according to the magnitude of the retarding potential applied to the substrate 101. Then, the deflection angle ratio determination unit 83 determines the deflection angle ratio for the two-stage deflectors 226 and 227 to be the calculated deflection angle ratio V_{L2}/V_{U2}. The determined deflection angle ratio V_{L2}/V_{U2} is output to the deflection control circuit 128.

Therefore, in Modification Example 2 of Embodiment 1, it is preferable to calculate Equations (4-1) to (4-8) and Equations (5-1) to (5-8) (Equations (6-1) to (6-8) and Equations (7-1) to (7-8)) using a deflection angle found by setting one of the deflection angle V_{U1}, which is a reference voltage applied to the first-stage deflector 209, and the deflection angle V_{L1}, which is a reference voltage applied to the second-stage deflector 209, as V1 and finding the other one using the deflection angle ratio V_{L1}/V_{U1}.

Similarly, in Modification Example 2 of Embodiment 1, it is preferable to calculate Equations (10-1) to (10-8) and Equations (11-1) to (11-8) using a deflection angle found by setting one of the deflection angle V_{U2}, which is a reference voltage applied to the first-stage deflector 226, and the deflection angle V_{L2}, which is a reference voltage applied to the second-stage deflector 227, as V2 and finding the other one using the deflection angle ratio V_{L2}/V_{U2}.

As described above, according to Embodiment 1, it is possible to correct aberrations according to the amount of scanning by the deflectors 209 and 208 even when the energy state of the beam changes. Similarly, it is possible to correct aberrations according to the amount of deflection back by the deflectors 226 and 227 even when the energy state of the beam changes.

In the above description, the series of “˜circuits” include a processing circuit, and the processing circuit includes an electric circuit, a computer, a processor, a circuit board, a quantum circuit, a semiconductor device, and the like. In addition, a common processing circuit (same processing circuit) may be used for the respective “˜circuits”. Alternatively, different processing circuits (separate processing circuits) may be used. A program for executing the processor and the like may be recorded on a record carrier body, such as a magnetic disk drive, a magnetic tape device, an FD, or a ROM (read only memory). For example, the position circuit 107, the comparison circuit 108, the reference image generation circuit 112, and the like may be configured by at least one processing circuit described above.

Up to now, the embodiments of the invention have been described with reference to specific examples. However, the invention is not limited to these specific examples. In the above example, a case has been described in which both the correction of aberration caused by scanning using the multiple primary electron beams 20 and the correction of aberration caused by deflection back using the multiple secondary electron beams 300 are performed, but the invention is not limited thereto. One of the correction of aberration caused by scanning using the multiple primary electron beams 20 or the correction of aberration caused by deflection back using the multiple secondary electron beams 300 may be performed.

The two-stage deflectors 208 and 209 and the two-stage deflectors 226 and 227 are not limited to two stages, but two or more stages may be adopted.

In addition, the description of parts that are not directly required for the description of the invention, such as the apparatus configuration or the control method, is omitted. However, the required apparatus configuration, control method, and the like can be appropriately selected and used.

In addition, all multi-electron beam image acquisition apparatuses, multi-electron beam image acquisition methods, electron beam image acquisition apparatuses, and electron beam image acquisition methods that include the elements of the invention and can be appropriately redesigned by those skilled in the art are included in the scope of the invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multi-electron beam image acquisition apparatus, comprising:
a stage, a substrate being placed on the stage;
a plurality of first electrostatic deflectors in two stages, each of the first electrostatic deflectors having a plurality of electrodes of quadrupoles or more, configured to deflect multiple primary electron beams collectively to scan the substrate with the multiple primary electron beams;
a separator configured to separate, from the multiple primary electron beams, multiple secondary electron beams emitted due to irradiation of the substrate with the multiple primary electron beams;
a multi-detector configured to detect the multiple secondary electron beams separated from the multiple primary electron beams;
a potential application circuit configured to apply a retarding potential to the substrate;
a first determination circuit configured to determine a first phase difference of deflection directions for the plurality of first electrostatic deflectors so as to reduce aberration caused by deflection of the multiple primary electron beams according to a magnitude of the retarding potential; and
a deflection control circuit configured to apply an individual potential according to the first phase difference of the deflection directions to each electrode of the plurality of first electrostatic deflectors.

2. The apparatus according to claim 1, further comprising:
a plurality of second electrostatic deflectors in two stages, each of the second electrostatic deflectors having a plurality of electrodes of quadrupoles or more, configured to fix positions of the multiple secondary electron beams on a detection surface of the multi-detector by deflecting the multiple secondary electron beams, the positions of the multiple secondary electron beams being changed by scanning using the multiple primary electron beams; and
a second determination circuit configured to determine a second phase difference of deflection directions for the plurality of second electrostatic deflectors so as to reduce aberration caused by deflection of the multiple secondary electron beams according to a magnitude of the retarding potential,
wherein the deflection control circuit further applies individual potentials to each electrode of the plurality of second electrostatic deflectors according to the second phase difference of the deflection directions.

3. The apparatus according to claim 1,
wherein the plurality of first electrostatic deflectors are arranged in the same phase.

4. The apparatus according to claim 1, further comprising:
an objective lens configured to image the multiple primary electron beams on the substrate,
wherein the plurality of first electrostatic deflectors are arranged between the separator and the objective lens.

5. The apparatus according to claim 2, further comprising:
a projection lens configured to project the multiple secondary electron beams onto the multi-detector,
wherein the plurality of second electrostatic deflectors are arranged between the separator and the projection lens.

6. A multi-electron beam image acquisition method, comprising:
Scanning a substrate placed on a stage with multiple primary electron beams by collectively deflecting the multiple primary electron beams using a plurality of first electrostatic deflectors in two stages each having a plurality of electrodes of quadrupoles or more;
separating, from the multiple primary electron beams, multiple secondary electron beams emitted due to irradiation of the substrate with the multiple primary electron beams;
detecting the multiple secondary electron beams separated from the multiple primary electron beams and outputting secondary electron images based on signals of detected multiple primary electron beams;
applying a retarding potential to the substrate;
determining a first phase difference of deflection directions for the plurality of first electrostatic deflectors so as to reduce aberration caused by deflection of the multiple primary electron beams according to a magnitude of the retarding potential; and
applying an individual potential according to the first phase difference of the deflection directions to each electrode of the plurality of first electrostatic deflectors.

7. An electron beam image acquisition apparatus, comprising:
a stage, a substrate being placed on the stage;
a plurality of first deflectors in two or more stages, each of the plurality of first deflectors having four or more poles, configured to deflect primary electron beam to scan the substrate with the primary electron beam;
a separator configured to separate, from the primary electron beam, a secondary electron beam emitted due to irradiation of the substrate with the primary electron beam;
a detector configured to detect the secondary electron beam separated from the primary electron beam;
a potential application circuit configured to apply a retarding potential to the substrate;
a first determination circuit configured to determine at least one of a first deflection angle ratio for the plurality of first deflectors in the two or more stages and a first phase difference of deflection directions for the plurality of first deflectors in the two or more stages so that a deflection aberration is equal to or less than a predetermined threshold value according to a magnitude of the retarding potential; and
a deflection control circuit configured to control the plurality of first deflectors in the two or more stages according to at least one of a determined first deflection angle ratio and a determined first phase difference.

8. The apparatus according to claim 7, further comprising:
a plurality of second deflectors in two or more stages, each of the second deflectors having four or more poles and fixing a position of the secondary electron beam on a detection surface of the detector by deflecting the secondary electron beam, the position of the secondary electron beam being changed by scanning using the primary electron beam; and
a second determination circuit configured to determine at least one of a second deflection angle ratio for the plurality of second deflectors in the two or more stages and a second phase difference of deflection directions of the plurality of second deflectors in the two or more stages so that a deflection aberration is equal to or less than a predetermined threshold value according to a magnitude of the retarding potential,
wherein the deflection control circuit further controls the plurality of second deflectors in the two or more stages according to at least one of the determined second deflection angle ratio and the determined second phase difference.

9. An electron beam image acquisition method, comprising:
scanning a substrate placed on a stage with a primary electron beam by deflecting the primary electron beam using a plurality of first deflectors in two or more stages, each of the first deflectors having four or more poles;
separating, from the primary electron beam, a secondary electron beam emitted due to irradiation of the substrate with the primary electron beam;
detecting the secondary electron beam separated from the primary electron beam and outputting a detected secondary electron image;
applying a retarding potential to the substrate;
determining at least one of a first deflection angle ratio for the plurality of first deflectors in the two or more stages and a first phase difference of deflection directions of the plurality of first deflectors in the two or more stages so that a deflection aberration is equal to or less than a predetermined threshold value according to a magnitude of the retarding potential; and
controlling the plurality of first deflectors in the two or more stages according to at least one of a determined first deflection angle ratio and a determined first phase difference.

10. A multi-electron beam image acquisition apparatus, comprising:
a stage, a substrate being placed on the stage;
a plurality of first electrostatic deflectors in two or more stages, each of the first electrostatic deflectors having a plurality of electrodes of quadrupoles or more, configured to deflect multiple primary electron beams collectively to scan the substrate with the multiple primary electron beams;
a separator configured to separate, from the multiple primary electron beams, multiple secondary electron beams emitted due to irradiation of the substrate with the multiple primary electron beams;
a multi-detector configured to detect the multiple secondary electron beams separated from the multiple primary electron beams;
a potential application circuit configured to apply a retarding potential to the substrate;
a first determination circuit configured to determine a first phase difference of deflection directions for the plurality of first electrostatic deflectors in the two or more stages so as to reduce aberration caused by deflection of the multiple primary electron beams according to a magnitude of the retarding potential; and
a deflection control circuit configured to apply an individual potential according to the first phase difference of the deflection directions to each electrode of the plurality of first electrostatic deflectors in the two or more stages.

11. A multi-electron beam image acquisition method, comprising:
Scanning a substrate placed on a stage with multiple primary electron beams by collectively deflecting the multiple primary electron beams using a plurality of first electrostatic deflectors in two or more stages, each of the plurality of first electrostatic deflectors having a plurality of electrodes of quadrupoles or more;
separating, from the multiple primary electron beams, multiple secondary electron beams emitted due to irradiation of the substrate with the multiple primary electron beams;
detecting the multiple secondary electron beams separated from the multiple primary electron beams and outputting a detected secondary electron image;
applying a retarding potential to the substrate;
determining a first phase difference of deflection directions for the plurality of first electrostatic deflectors in the two or more stages so as to reduce aberration caused by deflection of the multiple primary electron beams according to a magnitude of the retarding potential; and
applying an individual potential according to the first phase difference of the deflection directions to each electrode of the plurality of first electrostatic deflectors in the two or more stages.
